(19) United States
(12) Patent Application Publication
(10) Pub. No.: US 2022/0203412 A1
(43) Pub. Date: Jun. 30, 2022

(54) CHEMICAL LIQUID SUPPLY DEVICE AND APPARATUS FOR PROCESSING SUBSTRATE INCLUDING CHEMICAL LIQUID SUPPLY DEVICE

(71) Applicant: SEMES CO., LTD., Cheonan-si (KR)

(72) Inventors: Dogyeong Ha, Daegu (KR); Jaehyeok Yu, Hwaseong-si (KR); Gunmin Lee, Hongseong-gun (KR); Moonsoon Choi, Cheonan-si (KR); Chaeyoung Lim, Cheonan-si (KR)

(73) Assignee: SEMES CO., LTD., Cheonan-si (KR)

(21) Appl. No.: 17/404,314

(22) Filed: Aug. 17, 2021

(30) Foreign Application Priority Data
Dec. 29, 2020 (KR) 10-2020-0185633

(51) Int. Cl. B08B 3/14; B08B 3/02

(52) U.S. Cl. CPC B08B 3/14; B08B 2203/007; B08B 3/02

(57) ABSTRACT

An apparatus for processing a substrate may include a process chamber providing a processing space in which a predetermined process is performed on a substrate and a chemical liquid supply device for supplying a chemical liquid onto the substrate dispose din the process chamber. The chemical liquid supply device may include a chemical liquid supply reservoir for storing the chemical liquid, a chemical liquid supply line for providing a path through which the chemical liquid is supplied from the chemical liquid reservoir onto the substrate, at least one heating member for heating the chemical liquid provided from the chemical liquid reservoir, a sensing member including a first sensor for measuring a temperature of the chemical liquid entering the at least one heating member and a second sensor for measuring a temperature of the chemical liquid exiting the at least one heating member, and a control member for controlling an operation of the at least one heating member based on a difference between the temperatures measured by the first and the second sensors.

### CROSS-REFERENCE TO RELATED APPLICATION

This application claims priority to Korean Patent Application No. 10-2020-0185633 filed on Dec. 29, 2020 in the Korean Intellectual Property Office (KIPO), the contents of which are herein incorporated by reference in its entirety.

### BACKGROUND

### 1. Field

Example embodiments of the invention relate to a chemical liquid supply device and an apparatus for processing a substrate including the chemical liquid supply device. More particularly, example embodiments of the invention relate to a chemical liquid supply device capable of providing a chemical liquid having a desired temperature onto a substrate and an apparatus for processing a substrate including the chemical liquid supply device.

### 2. Related Technology

In general, a cleaning process is performed to remove particles or impurities remaining on a substrate in the manufacturing of an integrated circuit device including a semiconductor device or a display device including a flat panel display device. Here, the cleaning process can be performed using a chemical liquid such as isopropyl alcohol (IPA).

In the cleaning process, is it required that the chemical liquid has a temperature set in accordance with process conditions. Thus, the conventional chemical liquid supply device can include a chemical liquid reservoir storing the chemical liquid, a heating member heating the chemical liquid, a sensing member measuring the temperature of the chemical liquid heated by the heating member, and a control member controlling the heating member based on the temperature of the chemical liquid measured by the sensing member. Here, the chemical liquid can be continuously supplied from the chemical liquid reservoir as occasion demands.

In the conventional chemical liquid supply device, the heating member may be overheated and the heating member may excessively heat the chemical liquid since the heating member can be controlled based on the temperature of the chemical liquid after the chemical liquid having a relatively low temperature passes through the heating member from the chemical liquid reservoir.

### SUMMARY

One aspect of the invention provides a chemical liquid supply device capable of providing a chemical liquid having a temperature set according to process conditions onto a substrate.

Another aspect of the invention provides an apparatus for processing a substrate including a chemical liquid having a temperature set according to process conditions onto a substrate.

Still another aspect of the invention provides an apparatus for processing a substrate including a chemical liquid including isopropyl alcohol having a temperature set according to process conditions onto a substrate in a cleaning process.

According to one aspect of the invention, there is provided a chemical liquid supply device comprising a chemical liquid supply reservoir, a chemical liquid supply line, at least one heating member, a sensing member, and a control member. The chemical liquid supply reservoir may store a chemical liquid and the chemical liquid supply line may provide a path through which the chemical liquid is supplied from the chemical liquid reservoir onto a substrate. The at least one heating member may heat the chemical liquid provided from the chemical liquid reservoir. The sensing member may include a first sensor for measuring a temperature of the chemical liquid entering the at least one heating member and a second sensor for measuring a temperature of the chemical liquid exiting the at least one heating member. The control member may control an operation of the at least one heating member based on a difference between the temperatures measured by the first and the second sensors.

In example embodiments, the chemical liquid reservoir may include a single storage tank and a level sensor for measuring an amount of the chemical liquid so as to constantly maintain the amount of the chemical liquid stored in the chemical liquid reservoir.

In example embodiments, the chemical liquid supply device may additionally include a filtering member for removing impurities from the chemical liquid and a bubble removing member for removing bubbles from the chemical liquid.

In some example embodiments, the at least one heating member may include a first heating member to an Nth (N is an integer equal to or greater than 2) heating member arranged in serial. Additionally, the sensing member may include the first sensor and the second sensor to an N+1th sensor for measuring the temperatures of the chemical liquid entering or exiting the first heating member to the Nth heating member.

In some example embodiments, the chemical liquid supply device may additionally include a heating member sensor for measuring a temperature of the at least one heating member, and the control member may control the operation of the at least one heating member based on the temperature of the at least one heating member measured by the heating member sensor.

In example embodiments, the chemical liquid may include isopropyl alcohol.

According to another aspect of the invention, there is provided an apparatus for processing a substrate including a process chamber providing a processing space in which a predetermined process is performed on a substrate and a chemical liquid supply device for supplying a chemical liquid onto the substrate disposed in the process chamber. The chemical liquid supply device may include a chemical liquid supply reservoir for storing the chemical liquid, a chemical liquid supply line for providing a path through which the chemical liquid is supplied from the chemical liquid reservoir onto the substrate, at least one heating member for heating the chemical liquid provided from the chemical liquid reservoir, a sensing member including a first sensor for measuring a temperature of the chemical liquid entering the at least one heating member and a second sensor for measuring a temperature of the chemical liquid exiting the at least one heating member, and a control member for controlling an operation of the at least one heating member based on a difference between the temperatures measured by the first and the second sensors.

In example embodiments, the process chamber may include a rotation chuck for supporting the substrate and rotating the substrate.

In example embodiments, the chemical liquid reservoir may include a single storage tank and a level sensor for measuring an amount of the chemical liquid so as to constantly maintain the amount of the chemical liquid stored in the chemical liquid reservoir.

In example embodiments, the chemical liquid supply device may additionally include a filtering member for removing impurities from the chemical liquid and a bubble removing member for removing bubbles from the chemical liquid.

In some example embodiments, the at least one heating member may include a first heating member to an Nth (N is an integer equal to or greater than 2) heating member arranged in serial. In this case, the sensing member may include the first sensor and the second sensor to an N+1th sensor for measuring the temperatures of the chemical liquid entering or exiting the first heating member to the Nth heating member.

In some example embodiments, the chemical liquid supply device may additionally include a heating member sensor for measuring a temperature of the at least one heating member and the control member may control the operation of the at least one heating member based on the temperature of the at least one heating member measured by the heating member sensor.

In example embodiments, the chemical liquid may include isopropyl alcohol.

According to still another aspect of the invention, there is provided an apparatus for processing a substrate performing a cleaning process for cleaning the substrate using a chemical liquid. The apparatus for processing a substrate may include a process chamber including a rotation chuck for supporting and rotating the substrate and providing a processing space in which the cleaning process is performed on the substrate, and a chemical liquid supply device for supplying the chemical liquid including isopropyl alcohol onto the substrate placed in the process chamber. The chemical liquid supply device may include a chemical liquid supply reservoir for storing a chemical liquid, a chemical liquid supply line for providing a path through which the chemical liquid is supplied from the chemical liquid reservoir onto a substrate, at least one heating member for heating the chemical liquid provided from the chemical liquid reservoir, a sensing member including a first sensor for measuring a temperature of the chemical liquid entering the at least one heating member and a second sensor for measuring a temperature of the chemical liquid exiting the at least one heating member, and a control member for controlling an operation of the at least one heating member based on a difference between the temperatures measured by the first and the second sensors.

In example embodiments, the chemical liquid reservoir may include a single storage tank and a level sensor for measuring an amount of the chemical liquid so as to constantly maintain the amount of the chemical liquid stored in the chemical liquid reservoir.

In some example embodiments, the at least one heating member may include a first heating member to an Nth (N is an integer equal to or greater than 2) heating member arranged in serial. Here, the sensing member may include the first sensor and the second sensor to an N+1th sensor for measuring the temperatures of the chemical liquid entering or exiting the first heating member to the Nth heating member.

In some example embodiments, the chemical liquid supply device may additionally include a heating member sensor for measuring a temperature of the at least one heating member, and the control member may control the operation of the at least one heating member based on the temperature of the at least one heating member measured by the heating member sensor.

According to example embodiments of the invention, the control member may control the operation of the heating member based on the difference between the temperatures of the chemical liquid entering the heating member and exiting the heating member such that the control member may prevent the heating member from excessively heating the chemical liquid, insufficiently heating the chemical liquid or ununiformly heating the chemical liquid. Accordingly, the efficiency of the cleaning process performed on the substrate using the chemical liquid may be enhanced while preventing the failure of the cleaning process performed using the chemical liquid supply device such that impurities or particles may be effectively removed from the substrate by the cleaning process using the chemical liquid having the temperature satisfying the process conditions.

### BRIEF DESCRIPTION OF THE DRAWINGS

Example embodiments will be more clearly understood from the following detailed description taken in conjunction with the accompanying drawing. The following figures represent non-limiting, example embodiments as described herein.

FIG. 1 is a block diagram illustrating a chemical liquid supply device in accordance with example embodiments of the invention.

FIG. 2 is a block diagram illustrating a heating member and a sensing member in the chemical liquid supply device of FIG. 1.

FIG. 3 is a schematic cross sectional view illustrating an apparatus for processing a substrate in accordance with example embodiments of the invention.

### DESCRIPTION OF EMBODIMENTS

Various embodiments will be described more fully hereinafter with reference to the accompanying drawings, in which some embodiments are shown. The invention may, however, be embodied in many different forms and should not be construed as limited to the embodiments set forth herein. Rather, these embodiments are provided so that this description will be thorough and complete, and will fully convey the scope of the invention to those skilled in the art. In the drawings, the sizes and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numerals refer to like elements throughout. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the invention.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (for example, rotated 90 degrees or at other orientations) and the spatially relative descriptors used herein interpreted accordingly.

The terminology used herein is for the purpose of describing particular embodiments only and is not intended to be limiting of the invention. As used herein, the singular forms “a,” “an” and “the” are intended to include a plurality of forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Embodiments are described herein with reference to cross-sectional illustrations that are schematic illustrations of idealized embodiments (and intermediate structures). As such, variations from the shapes of the illustrations as a result, for example, of manufacturing techniques and/or tolerances, are to be expected. Thus, embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the face through which the implantation takes place. Thus, the regions illustrated in the figures are schematic in nature and their shapes are not intended to illustrate the actual shape of a region of a device and are not intended to limit the scope of the invention.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, example embodiments of the invention will be described in detail with reference to the accompanying drawings. Like elements or components can be indicated by like reference numerals throughout the drawings, and the repeated explanations of like elements or components may be omitted.

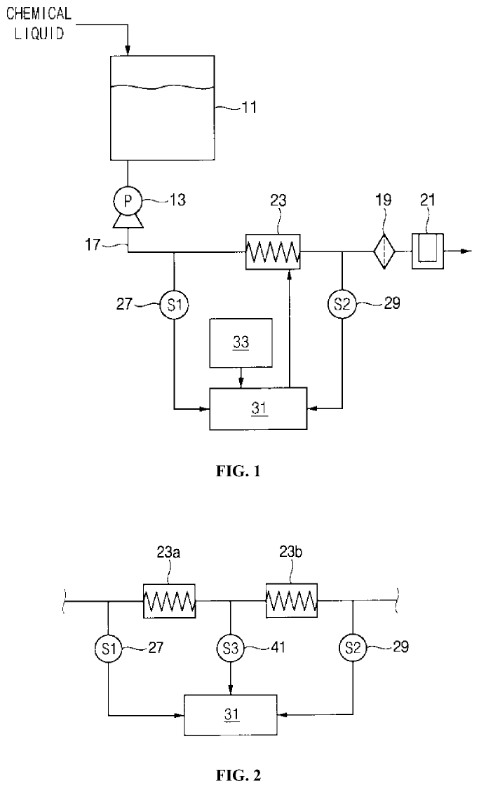

FIG. 1 is a block diagram illustrating a chemical liquid supply device in accordance with example embodiments of the invention. FIG. 2 is a block diagram illustrating a heating member and a sensing member in the chemical liquid supply device of FIG. 1.

Referring to FIG. 1 and FIG. 2, an apparatus for processing a substrate according to example embodiments may provide a chemical liquid onto a substrate in manufacturing processes for an integrated circuit device including a semiconductor device such as a volatile memory device, a non-volatile memory device, a system semiconductor device, etc. Particularly, the apparatus for processing a substrate may supply the chemical liquid onto the substrate in a cleaning process for cleaning the substrate. For example, the chemical liquid may include isopropyl alcohol (IPA).

In example embodiments, the chemical liquid supply device may include a chemical liquid reservoir 11, a pumping member 13, a chemical liquid supply line 17, a filtering member 19, a bubble removing member 21, at least one heating member 23, a sensing member, a heating member sensor 33, and a control member 31.

The chemical liquid reservoir 11 may store the chemical liquid supplied from an outside. In example embodiments, the chemical liquid reservoir 11 may include a single storage tank. Alternatively, the chemical liquid reservoir 11 may include a plurality of storage tanks. For example, the chemical liquid reservoir 11 may include at least two storage tanks.

The chemical liquid reservoir 11 may store a predetermined amount of chemical liquid. When the chemical liquid reservoir 11 includes the single storage tank, the single storage tank may have a storage capacity of more than 10 liters. The amount of the chemical liquid stored in the chemical liquid reservoir 11 may be constantly maintained. For example, a level sensor for measuring the amount of the chemical liquid may be installed in the chemical liquid reservoir 11 such that the amount of the chemical liquid in the chemical liquid reservoir 11 may be constantly maintained by adjusting the amount of the chemical liquid using the level sensor.

The chemical liquid supplied from an outside into the chemical liquid reservoir 11 may have a temperature substantially lower than that of the chemical liquid provided onto the substrate in the cleaning process. In other words, the temperature of the chemical liquid in the chemical liquid reservoir 11 may be relatively lower than the temperature of the chemical liquid supplied onto the substrate in the cleaning process because the chemical liquid may be supplied onto the substrate after the chemical liquid may be heated to a previously set temperature by the heating member 23 according to process conditions of the cleaning process.

The chemical liquid supply line 17 may provide a path through which the chemical liquid is supplied from the chemical liquid reservoir onto a substrate in the cleaning process.

The pumping member 13 may be disposed in the chemical liquid supply line 17. The pumping member 13 may provide the chemical liquid from the chemical liquid reservoir 11 onto the substrate during the cleaning process. For example, the pumping member 13 may include a rotary pump.

The filtering member 19 may remove undesired materials such as impurities or particles from the chemical liquid supplied onto the substrate via the heating member 23. For example, the filtering member 19 may include a membrane filter. The filtering member 19 may be disposed adjacent to the heating member 23. In example embodiments, the heating member 23 may be disposed between the pumping member 13 and the filtering member 19.

When the filtering member 19 includes the membrane filter, a pressure difference may be generated in the chemical liquid passing through the filtering member 19 because of the membrane filter. The pressure difference of the chemical liquid before the filtering member 19 and after the filtering member 19 may create bubbles in the chemical liquid. If the chemical liquid including the bubbles is supplied onto the substrate in the cleaning process, the chemical liquid may not sufficiently remove impurities or particles from the substrate. That is, the impurities or the particles may remain on the substrate after the cleaning process is performed on the substrate. Accordingly, the bubble removing member 21 may be disposed adjacent to the filtering member 19 in order to substantially completely remove the bubbles from the chemical liquid. For example, the bubble removing member 21 may include a bubble cutter.

In the chemical liquid supply device according to example embodiments, the filtering member 19 and the bubble removing member 21 may be sequentially disposed after the pumping member 13. The filtering member 19 may remove the undesired materials from the chemical liquid and the bubble removing member 21 may remove the bubbles from the chemical liquid such that the chemical liquid supplied onto the substrate may not substantially include the undesired materials and the bubbles. Accordingly, the cleaning process performed on the substrate using the chemical liquid may ensure an improved efficiency.

When the chemical liquid is provided onto the substrate in a state that the temperature of the chemical liquid does not reach the previously set temperature according to the process conditions of the cleaning process, the chemical liquid may not sufficiently remove the impurities or the particles from the substrate so that failure of the cleaning process may occur. In example embodiments, the heating member 23 of the apparatus for processing a substrate may heat the chemical liquid such that the temperature of the chemical liquid reaches the previously set temperature according to the process conditions. In this case, the control member 31 may control the operations of the heating member 23, the sensing member and the heating member sensor 33 so as to adjust the temperature of the chemical liquid.

In example embodiments, the sensing member may include a first sensor 27 and a second sensor 29. The first sensor 27 may measure a first temperature of the chemical liquid entering the heating member 23 (i.e., the temperature of the chemical liquid before the chemical liquid passes through the heating member 23). The second sensor 29 may measure a second temperature of the chemical liquid exiting the heating member 23 (i.e., the temperature of the chemical liquid after the chemical liquid passes through the heating member 23).

The control member 31 may control the operation of the heating member 23 based on the first temperature of the chemical liquid transmitted from the first sensor 27 and the second temperature of the chemical liquid transmitted from the second sensor 29. In other words, the control member 31 may control the operation of the heating member 23 based on the difference between the first temperature and the second temperature measured by the first sensor 27 and the second sensor 29, respectively.

In example embodiments, the control member 31 may control the operation of the heating member 23 such that the heating member 23 does not excessively heat the chemical liquid. That is, the control member 31 may prevent the temperature of the chemical liquid from being higher than the previously set temperature by the heating member 23. Further, the control member 31 may control the operation of the heating member 23 so that the heating member 23 does not insufficiently heat the chemical liquid. In other words, the control member 31 may prevent the temperature of the chemical liquid from being lower than the previously set temperature by the heating member 23. Therefore, the temperature of the chemical liquid passing through the heating member 23 may be substantially the same as the previously set temperature according to the process conditions. Alternatively, the temperature of the chemical liquid exiting the heating member 23 may be substantially higher than the previously set temperature considering the situation that the chemical liquid passes through the filtering member 19 and the bubble removing member 21.

As described above, the chemical liquid supply device according to example embodiments may include the heating member 23, the sensing member and the control member 31 so that the temperature of the chemical liquid supplied onto the substrate may satisfy the process conditions of the cleaning process. In other words, the chemical liquid supply device may prevent the temperature of the chemical liquid provided onto the substrate from being lower or excessively higher than the previously set temperature according to the process conditions.

The conventional chemical liquid supply device can control the operation of the heating member based on only the temperature of the chemical liquid after the chemical liquid passes through the heating member. Thus, when the chemical liquid having a relatively low temperature is sequentially passes through the heating member, the heating member can excessively operate in order to heat the chemical liquid sequentially supplied from the chemical liquid reservoir. That is, the heating member can excessively heat the chemical liquid, or can substantially uniformly heat the entire chemical liquid. As a result, the chemical liquid exiting the heating member cannot have the temperature satisfying the process conditions.

According to example embodiments, the control member 31 may control the operation of the heating member 23 based on the difference between the first temperature of the chemical liquid entering the heating member 23 and the second temperature of the chemical liquid exiting the heating member 23 such that the control member 31 may prevent the heating member 23 from excessively heating the chemical liquid, insufficiently heating the chemical liquid or ununiformly heating the chemical liquid. Accordingly, the efficiency of the cleaning process executed on the substrate using the chemical liquid may be enhanced while preventing the failure of the cleaning process performed using the chemical liquid supply device. That is, the impurities or the particles may be effectively removed from the substrate by the cleaning process using the chemical liquid having the temperature satisfying the process conditions.

In example embodiments, the chemical liquid supply device may adjust the heating member 23 by measuring the difference between the temperatures of the chemical liquid before and after the heating member 23. Therefore, the chemical liquid supply device may exactly maintain the temperature of the chemical liquid according to the process conditions and also may prevent the overheating of the heating member 23.

In some example embodiments, the heating member sensor 33 of the chemical liquid supply device may measure a temperature of the heating member 23. For example, the heating member sensor 33 may measure a temperature of an inside of the heating member 23 and/or a temperature of a surface of the heating member 23. Accordingly, the chemical liquid supply device may stably control the operation of the heating member 23 additionally utilizing the temperature of the heating member 23 by the heating member sensor 33.

When the chemical liquid supply device includes the first sensor 27, the second sensor 29 and the heating member sensor 33, the chemical liquid supply device may provide an optimized output to the operation of the heating member 23 by utilizing the first temperature of the chemical liquid measured by the first sensor 27, the second temperature of the chemical liquid measured by the second sensor 29 and the temperature of the heating member 23 measured by the heating member sensor 33.

In some example embodiments, the chemical liquid supply device may include a plurality of heating members 23. In this case, the plurality of heating members 23 may be arranged in serial. As illustrated in FIG. 2, the chemical liquid supply device includes a first heating member 23a and a second heating member 23b arranged in serial, the first sensor 27 may be disposed before the first heating member 23a and the second sensor 29 may be disposed after the second heating member 23b. Additionally, the sensing member may include a third sensor 41 disposed between the first heating member 23a and the second heating member 23b.

In other example embodiments, the chemical liquid supply device may include a first heating member, a second heating member and a third heating member arranged in serial. In this case, the sensing member may include a first sensor located before the first heating member, a second sensor located after the third heating member, a third sensor located between the first heating member and the second heating member, and a fourth sensor located between the second heating member and the third heating member.

According to example embodiments of the invention, the chemical liquid supply device may include the first heating member 23a to an Nth (N is an integer equal to or greater than 2) heating member arranged in serial. Here, the sensing member may include the first sensor 27 to an N+1th (N is an integer equal to or greater than 2) sensor for the temperatures of the chemical liquid entering and/or exiting the first heating member 23a to the Nth heating member. For example, the first sensor 27 may measure the temperature of the chemical liquid entering the first heating member 23a and the N+1th sensor may measure the temperature of the chemical liquid exiting the N+1th heating member.

When the chemical liquid supply device includes the plurality of heating members, the sensing member may include a plurality of sensors measuring the temperatures of the chemical liquid entering and/or exiting each of the heating members. The control member of the chemical liquid supply device may control the operation of each of the heating members based on the temperatures of the chemical liquid measured by the plurality of sensors so that the chemical liquid supply device may prevent some or all of the plurality of heating members from excessively heating the chemical liquid or insufficiently heating the chemical liquid. Therefore, the chemical liquid supply device may provide the chemical liquid having the temperature, which is more uniform and more satisfies the process conditions, onto the substrate.

In example embodiments, the chemical liquid reservoir 11 of the chemical liquid supply device may be purged using an inactive gas. Therefore, the impurities or the particles contained in the chemical liquid may be reduced. For example, the inactive gas may include nitrogen (N₂) gas.

Hereinafter, it will be described an apparatus for processing a substrate including the chemical liquid supply device according to example embodiments.

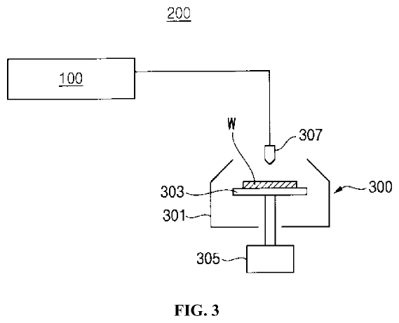

FIG. 3 is a schematic cross sectional view illustrating an apparatus for processing a substrate in accordance with example embodiments of the invention.

Referring to FIG. 3, an apparatus for processing a substrate 200 according to example embodiments may perform a predetermined process on a substrate W for manufacturing an integrated circuit device including a semiconductor device or a display device including a flat panel display device. In particular, the apparatus for processing a substrate 200 may perform a cleaning process for cleaning the substrate W using a chemical liquid including isopropyl alcohol.

In example embodiments, the apparatus for processing a substrate 200 may include a process chamber 300 and a chemical liquid supply device 100. The process chamber 300 may provide a processing space in which the substrate W is placed and the cleaning process is performed.

The process chamber 300 may include a housing 301 for providing the processing space therein, a rotation chuck 303 for supporting and rotating the substrate W, a driving member 305 for rotating the rotation chuck 305, and a nozzle 307 for supplying the chemical liquid onto the substrate W provided from the chemical liquid supply device 100.

The rotation chuck 303 may rotate the substrate W while the chemical liquid is supplied from the chemical liquid supply device 100 onto the substrate W such that the chemical liquid may be substantially uniformly provided onto the entire surface of the substrate W from the nozzle 307. In this case, droplets of the chemical liquid may be dispersed toward the outside by mean of the centrifugal force generated by the rotation of the substrate W, and thus the housing 301 may have a shape capable of retrieving the dispersed droplets of the chemical liquid.

The apparatus for processing a substrate 200 may include the chemical liquid supply device 100 described with reference to FIG. 1 or FIG. 2 so that the efficiency of cleaning process performed on the substrate W may be considerably enhanced. Therefore, the integrated circuit device including the semiconductor device or the display device including the flat panel display device manufactured using the apparatus for processing a substrate 200 may ensure improved performance and enhanced reliability.

The foregoing is illustrative of embodiments and is not to be construed as limiting thereof. Although a few embodiments have been described, those skilled in the art will readily appreciate that many modifications are possible in the embodiments without materially departing from the novel teachings and advantages of the invention. Accordingly, all such modifications are intended to be included within the scope of the invention as defined in the claims. In the claims, means-plus-function clauses are intended to cover the structures described herein as performing the recited function and not only structural equivalents but also equivalent structures. Therefore, it is to be understood that the foregoing is illustrative of various embodiments and is not to be construed as limited to the specific embodiments disclosed, and that modifications to the disclosed embodiments, as well as other embodiments, are intended to be included within the scope of the appended claims.

What is claimed is:

1. A chemical liquid supply device comprising:
a chemical liquid supply reservoir for storing a chemical liquid;
a chemical liquid supply line for providing a path through which the chemical liquid is supplied from the chemical liquid reservoir onto a substrate;
at least one heating member for heating the chemical liquid provided from the chemical liquid reservoir;
a sensing member including a first sensor for measuring a temperature of the chemical liquid entering the at least one heating member and a second sensor for measuring a temperature of the chemical liquid exiting the at least one heating member; and
a control member for controlling an operation of the at least one heating member based on a difference between the temperatures measured by the first and the second sensors.

2. The chemical liquid supply device of claim 1, wherein the chemical liquid reservoir includes a single storage tank and a level sensor for measuring an amount of the chemical liquid so as to constantly maintain the amount of the chemical liquid stored in the chemical liquid reservoir.

3. The chemical liquid supply device of claim 2, further comprising a filtering member for removing impurities from the chemical liquid and a bubble removing member for removing bubbles from the chemical liquid.

4. The chemical liquid supply device of claim 1, wherein the at least one heating member includes a first heating member to an Nth (N is an integer equal to or greater than 2) heating member arranged in serial.

5. The chemical liquid supply device of claim 4, wherein the sensing member includes the first sensor and the second sensor to an N+1th sensor for measuring the temperatures of the chemical liquid entering or exiting the first heating member to the Nth heating member.

6. The chemical liquid supply device of claim 1, further comprising a heating member sensor for measuring a temperature of the at least one heating member wherein the control member controls the operation of the at least one heating member based on the temperature of the at least one heating member measured by the heating member sensor.

7. The chemical liquid supply device of claim 1, wherein the chemical liquid includes isopropyl alcohol.

8. An apparatus for processing a substrate, comprising:
a process chamber providing a processing space in which a predetermined process is performed on a substrate; and
a chemical liquid supply device for supplying a chemical liquid onto the substrate disposed in the process chamber,
wherein the chemical liquid supply device comprises:
a chemical liquid supply reservoir for storing the chemical liquid;
a chemical liquid supply line for providing a path through which the chemical liquid is supplied from the chemical liquid reservoir onto the substrate;
at least one heating member for heating the chemical liquid provided from the chemical liquid reservoir;
a sensing member including a first sensor for measuring a temperature of the chemical liquid entering the at least one heating member and a second sensor for measuring a temperature of the chemical liquid exiting the at least one heating member; and
a control member for controlling an operation of the at least one heating member based on a difference between the temperatures measured by the first and the second sensors.

9. The apparatus for processing a substrate of claim 8, wherein the process chamber includes a rotation chuck for supporting the substrate and rotating the substrate.

10. The apparatus for processing a substrate of claim 8, wherein the chemical liquid reservoir includes a single storage tank and a level sensor for measuring an amount of the chemical liquid so as to constantly maintain the amount of the chemical liquid stored in the chemical liquid reservoir.

11. The apparatus for processing a substrate of claim 8, wherein the chemical liquid supply device further includes a filtering member for removing impurities from the chemical liquid and a bubble removing member for removing bubbles from the chemical liquid.

12. The apparatus for processing a substrate of claim 8, wherein the at least one heating member includes a first heating member to an Nth (N is an integer equal to or greater than 2) heating member arranged in serial.

13. The apparatus for processing a substrate of claim 12, wherein the sensing member includes the first sensor and the second sensor to an N+1th sensor for measuring the temperatures of the chemical liquid entering or exiting the first heating member to the Nth heating member.

14. The apparatus for processing a substrate of claim 8, wherein the chemical liquid supply device further comprises a heating member sensor for measuring a temperature of the at least one heating member wherein the control member controls the operation of the at least one heating member based on the temperature of the at least one heating member measured by the heating member sensor.

15. The apparatus for processing a substrate of claim 8, wherein the chemical liquid includes isopropyl alcohol.

16. An apparatus for processing a substrate performing a cleaning process for cleaning the substrate using a chemical liquid, which comprises:
a process chamber including a rotation chuck for supporting and rotating the substrate, and providing a processing space in which the cleaning process is performed on the substrate; and
a chemical liquid supply device for supplying the chemical liquid including isopropyl alcohol onto the substrate placed in the process chamber,
wherein the chemical liquid supply device comprises:
a chemical liquid supply reservoir for storing a chemical liquid;
a chemical liquid supply line for providing a path through which the chemical liquid is supplied from the chemical liquid reservoir onto a substrate;
at least one heating member for heating the chemical liquid provided from the chemical liquid reservoir;
a sensing member including a first sensor for measuring a temperature of the chemical liquid entering the at least one heating member and a second sensor for measuring a temperature of the chemical liquid exiting the at least one heating member; and
a control member for controlling an operation of the at least one heating member based on a difference between the temperatures measured by the first and the second sensors.

17. The apparatus for processing a substrate of claim 16, wherein the chemical liquid reservoir includes a single storage tank and a level sensor for measuring an amount of the chemical liquid so as to constantly maintain the amount of the chemical liquid stored in the chemical liquid reservoir.

18. The apparatus for processing a substrate of claim 16, wherein the at least one heating member includes a first heating member to an Nth (N is an integer equal to or greater than 2) heating member arranged in serial.

19. The apparatus for processing a substrate of claim 18, wherein the sensing member includes the first sensor and the second sensor to an N+1th sensor for measuring the temperatures of the chemical liquid entering or exiting the first heating member to the Nth heating member.

20. The apparatus for processing a substrate of claim 16, wherein the chemical liquid supply device further comprises a heating member sensor for measuring a temperature of the at least one heating member wherein the control member controls the operation of the at least one heating member based on the temperature of the at least one heating member measured by the heating member sensor.
